(19) United States
(12) Patent Application Publication
(10) Pub. No.: US 2005/0230753 A1
(43) Pub. Date: Oct. 20, 2005

(54) LTPS TFT substrate and manufacturing process thereof

(75) Inventors: Tsau Hua Hsieh, Miao-Li (TW); Jia-Pang Pang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/109,235

(22) Filed: Apr. 18, 2005

(30) Foreign Application Priority Data
Apr. 16, 2004 (TW) 93110620

(51) Int. Cl. H01L 27/01

(52) U.S. Cl. 257/347

(57) ABSTRACT

An LTPS TFT substrate includes an insulated substrate and a poly-silicon film formed on the insulated substrate. The poly-silicon film includes a driving circuit area and a display area. The driving circuit area includes a plurality of driving circuits. The display area includes a plurality of pixel units. The driving circuit area and the display area are separately fabricated. This approach reduces the impediment to uniformity that is caused by the process variety, and thus improves the yield rate and reduces production costs.

### FIELD OF THE INVENTION

The present invention relates to a thin film transistor substrate of low temperature poly-silicon and a process for manufacture thereof.

### BACKGROUND OF THE INVENTION

The amorphous silicon thin film transistor liquid crystal display (a-Si TFT-LCD) has been a major product in the market as an alternative to the conventional cathode ray tube display (CRT-display) because of the a-Si TFT-LCD's thinness and light weight. However, information technology is continuing to advance rapidly, and the market requirements for resolution and data transmittance have become so high that many a-si TFT-LCDs can no longer meet these requirements. Thus, the industry has developed a superior technology, which is known as low temperature poly-silicon thin film transistor (LTPS TFT). The superiority of the LTPS TFT-LCD is that the driving circuit can be fabricated on the glass substrate (also called system on glass—SOG). This means that the cost of the integrated driving circuit can be reduced, while still meeting stringent requirements for resolution and data transmittance.

The general technology of LTPS TFTs at least comprises thin film deposition, laser annealing, lithography, and etching processes. These processes would manufacture the thin film transistors and the pixel electrodes on the glass substrate. The laser annealing process is the most important step in these processes. The success or otherwise of the laser annealing process greatly impacts the characteristics of the thin film transistors produced.

A prior art LTPS TFT-LCD is found in U.S. patent application publication No. 2004/0018649, which was published on Jan. 29, 2004. Referring to FIG. 4, this is an isometric structural view of an LTPS TFT substrate according to the prior art. The LTPS TFT substrate 100 is manufactured by performing the following steps. First, a glass substrate 110 to be the base of the LTPS TFT substrate 100 is provided. An amorphous silicon film 112 is formed on a surface of the glass substrate 110. The amorphous silicon film 112 comprises a first area 114 and a second area 116. The first area 114 is located in the center of the amorphous silicon film 112. The second area 116 is at the periphery, and has a slanted wall. The thickness distribution of the slanted wall determines the boundary condition of the laser annealing process. The thickness of the amorphous silicon film 112 in the first area 114 is a predetermined value. Then, the substrate 110 is put into a chamber for excimer laser annealing, to make the amorphous silicon film 112 transform into a poly-silicon film. When the thickness of the amorphous silicon film in the boundary condition is larger than a threshold, usually 400 Å, an ablation phenomenon occurs in the amorphous silicon film such that any film higher than the threshold thickness is removed. Finally, a driving circuit area and a display panel area are produced in the glass substrate 110.

Referring to FIG. 5, this is a structural plan view of another LTPS TFT substrate according to the prior art. The LTPS TFT substrate 200 comprises an insulating substrate 220, a driving circuit area 210, and a display panel area 230. In the prior art, the driving circuit area 210 and the display panel area 230 are connected together. The plurality of driving circuits 211 is set in the driving circuit area 210. The plurality of pixel units 222 is set in the display panel area 230. Each driving circuit 211 is set corresponding to each pixel unit 222. The excimer laser annealing process is repeated several times to make the thin film transistors on the substrate 220, so the characteristic of each thin film transistor should be different. The requirement (±10˜100 mV) of the characteristic uniformity of the TFTs in the driving circuit area 210 is much higher than the requirement (±1˜2V) of the TFTs in the display panel area 230. Furthermore, the layout of the general LTPS TFT substrate 200 is such that each driving circuit 211 is distributed corresponding to the pixel unit 222 in the substrate 220. Thus, it is hard to achieve the uniformity requirements during the production process. When the uniformity of the process is lower than a threshold requirement, some driving circuits 211 are destroyed, and the display panel area 230 corresponding to the lost driving circuits 211 is also destroyed. This decreases the yield rate and increases costs.

In view of the above, it is desired to provide a new LTPS TFT substrate to solve the problems of the low yield rate and high costs of conventional low-uniformity LTPS TFT substrates.

### SUMMARY

An object of the present invention is to provide an LTPS TFT substrate to solve or at least ameliorate the drawbacks of low yield rate and high costs of the prior art.

Another object of the present invention is to provide a method for manufacturing the above-described LTPS TFT substrate.

The present invention provides a LTPS TFT substrate that comprises an insulated substrate and a poly-silicon film on said insulated substrate. The poly-silicon film comprises a driving circuit area and a display area. The driving circuit area comprises a plurality of driving circuits. The display area comprises a plurality of pixel units. The driving circuit area and the display area are separately fabricated.

The present invention further provides a method of manufacturing the LTPS TFT substrate, which comprises the following steps. First, provide an insulated substrate, and perform the first Plasma Enhanced Chemical Vapor Deposition (PECVD) on the surface of the insulated substrate to form an amorphous silicon film. Then, perform an annealing process to make the amorphous silicon film re-crystallize to a poly-silicon film. Finally, perform a second Plasma Enhanced Chemical Vapor Deposition (PECVD) to form a silicon oxide layer which major composition is tetra-ethyl-ortho-silicate (TEOS) in the channel area.

Compared to the prior art, the present invention provides a technology to manufacture the driving circuit area and the display area separately, and to centralize the driving circuit in the same area. This approach reduces the impediment to uniformity that is caused by the process variety, and thus improves the yield rate and reduces production costs. After the driving circuit area and the display area have been fabricated, a soft circuit board is used to connect them.

Other objects, advantages, and novel features will become more apparent from the following detailed description when taken in conjunction with the accompanying drawings, in which:

### BRIEF DESCRIPTION OF THE DRAWINGS

FIG. 1 is a structural plan view of an LTPS TFT substrate according to an embodiment of the present invention;

FIG. 2 is a flow chart of an exemplary method for manufacturing the LTPS TFT substrate of FIG. 1;

FIG. 3 is a diagram showing the connection of a driving circuit area and a display area of the LTPS TFT substrate of FIG. 1;

FIG. 4 is an isometric structural view of an LTPS TFT substrate according to the prior art; and

FIG. 5 is a structural plan view of another LTPS TFT substrate according to the prior art.

### DETAILED DESCRIPTION OF THE PRESENT EMBODIMENTS

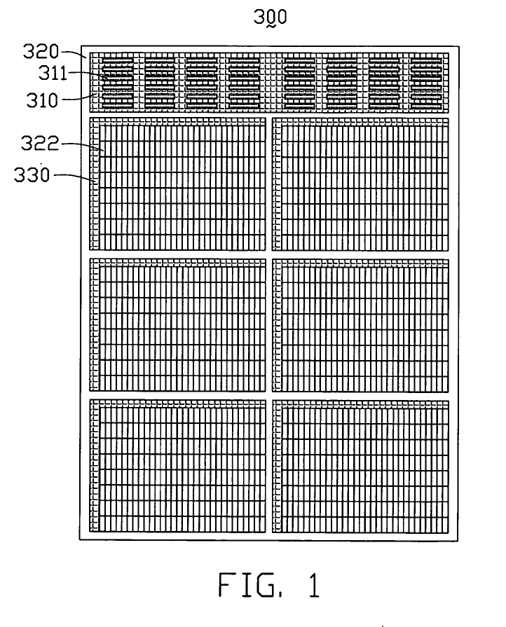

Referring to FIG. 1, this is a structural plan view of an LTPS TFT substrate according to an embodiment of the present invention. The LTPS TFT substrate 300 comprises an insulated substrate 320, a driving circuit area 310, a plurality of driving circuits 311, a display area 330, and a plurality of pixel units 322. The driving circuit area 310 and the display area 330 are manufactured on the same insulated substrate 320, but in different areas. The plurality of driving circuits 311 are set in the driving circuit area 310, and the plurality of the pixel units 322 are set in the display area 330.

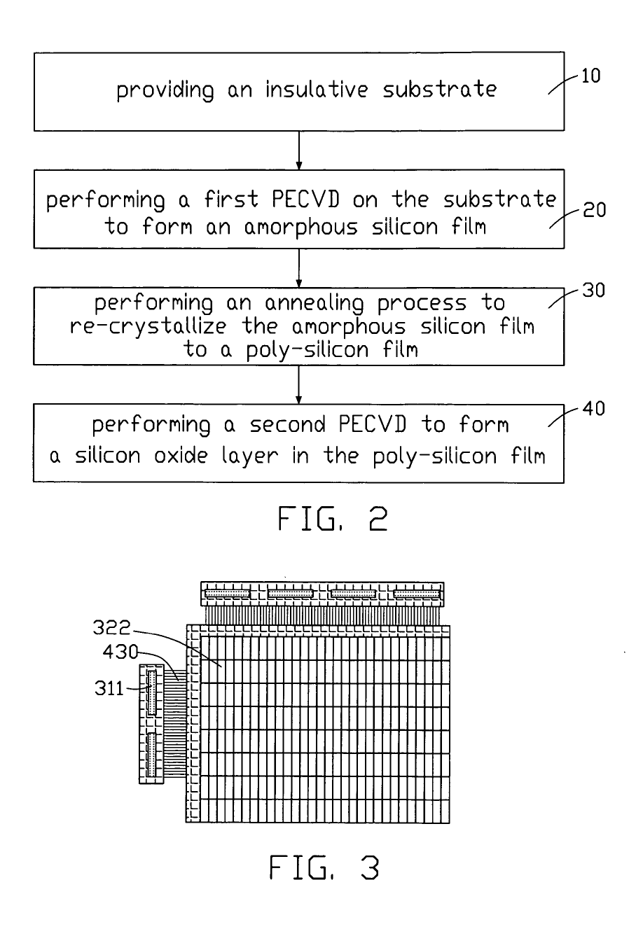

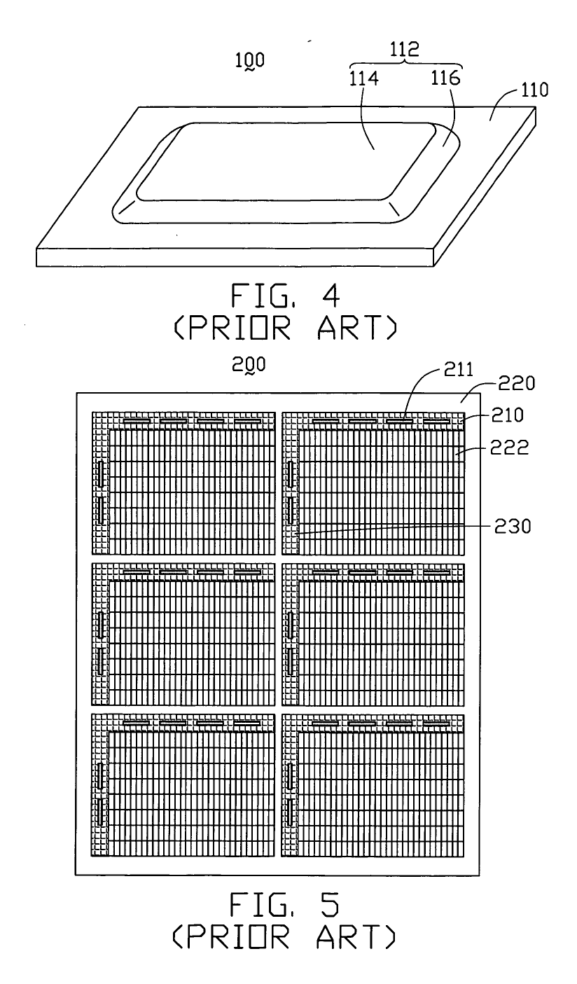

Referring to FIG. 2, this is a flow chart of an exemplary method for manufacturing the LTPS TFT substrate 300. The method comprises the following steps. First, an insulated substrate 320 is provided (step 10). The insulated substrate 320 is typically a glass substrate or a quartz substrate. Next, a first Plasma Enhanced Chemical Vapor Deposition (PECVD) is performed on a major surface of the insulated substrate 320 to form an amorphous silicon film (step 20). Then, an annealing process is performed to re-crystallize the amorphous silicon film to a poly-silicon film (step 30). The poly-silicon film comprises a source area, a drain area, and a channel area of the LTPS TFT. Finally, in the channel area, a second PECVD is performed to form a silicon oxide layer on the poly-silicon film (step 40). A major constituent of the silicon oxide layer is tetra-ethyl-ortho-silicate (TEOS). At the same time, the driving circuit area 310 and the display area 330 on the insulated substrate 320 are separated. The driving circuit area 310 comprises the plurality of driving circuits 311, and the display area 330 comprises the plurality of pixel units 322. In the present invention, the driving circuit area and the display area are manufactured separately, and the driving circuits are centralized in the same area. This reduces the impediment to uniformity that is caused by the process variety, and thus improves the yield rate and reduces production costs.

Referring to FIG. 3, this is a diagram showing the connection of the driving circuit area 310 and the display area 330 of the LTPS TFT substrate 300. The pins of the driving circuits 311 are connected to the pins of the TFT matrix of the pixel units 322 by a soft circuit board 430 or another suitable conducting mechanism. After that, the corresponding TFT LCD panel is fabricated.

It is to be understood, however, that even though numerous characteristics and advantages of the present embodiments have been set forth in the foregoing description, together with details of the structure and function of the embodiments, the disclosure is illustrative only, and changes may be made in detail, especially in matters of shape, size, and arrangement of parts, within the principles of the invention to the full extent indicated by the broad general meaning of the terms in which the appended claims are expressed.

1. An LTPS TFT substrate comprising:
an insulated substrate;
a poly-silicon film formed on the insulated substrate;
a driving circuit area formed on the poly-silicon film, the driving circuit area comprising a plurality of driving circuits; and
a display area formed on the poly-silicon film, the display area comprising a plurality of pixel units;
wherein the driving circuit area and the display area are separately manufactured.

2. The LTPS TFT substrate of claim 1, wherein the insulated substrate is a glass substrate.

3. The LTPS TFT substrate of claim 1, wherein the insulated substrate is a quartz substrate.

4. The LTPS TFT substrate of claim 1, wherein the poly-silicon film is manufactured by an excimer laser annealing process.

5. The LTPS TFT substrate of claim 1, wherein a surface of the poly-silicon film comprises a drain area, a source area, and a channel area.

6. A method for manufacturing an LTPS TFT substrate, comprising:
providing an insulated substrate;
performing a first plasma enhanced chemical vapor deposition to form an amorphous silicon film on a surface of the insulated substrate;
performing an annealing process to re-crystallize the amorphous silicon film to a poly-silicon film; and
performing a second plasma enhanced chemical vapor deposition to form a silicon oxide layer on the poly-silicon film, wherein a major constituent of the silicon oxide layer is tetra-ethyl-ortho-silicate.

7. The method of claim 6, wherein the insulated substrate is a glass substrate.

8. The method of claim 6, wherein the insulated substrate is a quartz substrate.

9. The method of claim 6, wherein the poly-silicon film is manufactured by an excimer laser annealing process.

10. The method of claim 6, wherein a surface of the poly-silicon film comprises a drain area, a source area, and a channel area.

11. The method of claim 10, wherein the silicon oxide layer is formed in the channel area.

12. An LTPS TFT module comprising:
a driving circuit area comprising a plurality of driving circuits and; and
a display area comprising a plurality of pixel units;
wherein the driving circuit area and the display area are spaced from each other and not located on a same continuous substrate, while connected with each other via another conductive element.

13. The LTPS TFT module as claimed in claim 12, wherein a first substrate the driving circuit area is located and a second substrate the display area is located, are spaced from each other and experience different and isolated processes during manufacturing so as not to influence each other.

14. The LTPS TFT module as claimed in claim 12, wherein said conductive element is a flexible printed circuit board.
